(19) United States
(12) Patent Application Publication
(10) Pub. No.: US 2003/0235040 A1
(43) Pub. Date: Dec. 25, 2003

(54) Common signal connector for a storage card

(76) Inventors: Wen-Tsung Liu, Shindian City (TW); Chia-Li Chen, Shindian City (TW)

Correspondence Address: Carry Computer Eng. Co., Ltd., P.O Box No.6-57, Chung-Ho, Taipei, 235, TW

(21) Appl. No.: 10/302,921

(22) Filed: Nov. 25, 2002

(30) Foreign Application Priority Data
Jun. 21, 2002 (TW) 091209374

(51) Int. Cl. H05K 1/14

(52) U.S. Cl. 361/737

(57) ABSTRACT

A common signal connector for a storage card including a controller circuit board, a connector allowing storage cards of various dimensions to insert and position at different times, a frame, an upper and a lower metal plates is characterized that the connector is a unitarily molded insert slot with a plurality of guide slots; only one lateral side of the connector is disposed with one or more than one row of contact terminals; one end portion of the contact terminals protrudes beyond said lateral side to engage with a plurality of through holes of the corresponding circuit board thereby directly controlling and converting the storage card signal into the connector interface signal for input and output through the circuit arrangement on the circuit board.

### BACKGROUND OF THE INVENTION

1) Field of the Invention

The present invention relates to a connector, more particularly to a common signal connector for a storage card.

2) Description of the Prior Art

Currently, portable memory device products are mainly categorized as three kinds—the magnetic memory, the magnetic or optical disks of optical storage technique as well as the erasable and writable flash memory of semiconductor technique; wherein the products of flash memory are most popular and focused by both the industrials and the customers. Usually, they are called storage cards or miniature cards, such as PCMCIA ATA Flash (PC) Card, Compact Flash (CF) Card, Smart Media (SM) Card, Multi Media Card (MMC), Memory Stick (MS) Card, Secure Digital (SD) Card. In terms of the convenient portability, electricity saving, material conservation, data transmission speed, repetitive reading and writing, anti-vibration and moisture-proof, the flash memory products surpass said two traditional storage media. They have been extensively applied onto some mobile and household electronic products, such as a digital camera, a digital camcorder and a personal digital assistant (PDA). In addition, they have been applied to some new portable devices too, such as the Smart Phone, the vehicle computer, the mobile phone, the Multimedia Player Level 3 (MPs) Walkman and the Global Positioning System.

With the support and leading from all the major manufacturers as well as the trend of making the ultimate customer's applicable product more extensive in usage, the consuming market of storage cards holds a tremendous potential. However, except the possessive advantages and price factors, the major incentive is the acceptability of the product. In other words, both of the size of the disposed connector and the connectivity between various storage cards and the connectors influence the popularity of the product on the market. As a matter of fact, the original and main function of the portable memory device at the early stage focuses on the desktop or notebook computer and PCMCIA interface; at the later stage, the focuses shift to the digital camera and other information household electronic appliances such as the PDA, the interface of CF, SD/MMC and MS. However, the relative high price and the various dimensions of the storage cards on the market are some of the major factors of disabling the products to completely enter the market.

For stimulating the consuming market, promoting the extensive application of the storage card on the final end product and possibly integrating cards of different dimensions onto a mono machine, some read and write loaders capable of supporting a plurality of storage cards of different dimensions are available, for example, the Republic of China Patent No. 182880M, “Signal Connector of a Memory Card” and the Japan New Patent No. 3084232, “Multiple-in-One Silicon Disk Drives”. However, for any read and write loader, the connector is used to receive the storage cards of various dimensions.

FIG. 1 shows an exploded drawing of applying a connector onto the signal connector. A conventional connector is assembled by an upper base plate (20), a lower base plate (30) and a base (10); wherein the base (10) allows three storage cards of different dimensions to insert at the same time. The base plates (20, 30) are disposed fixedly on the top and bottom sides of the base (10). The sides of the base plates (20, 30) facing the base (10) fit the contact terminals of the storage cards of various dimensions inserted into the base (10). More especially, after connecting with the upper and lower base plates (20, 30), the base (10) has more signal terminals (201) to connect with a circuit board (31). In addition, the assembled contact terminals are soldered onto the upper and lower base plates (20, 30).

Therefore, the manufacturing procedure of the conventional connector is very complicate and that further increases the cost. In addition, it is necessary to dispose a positioning resilient tab, a card detect switch for detecting the property of the inserted storage card and a write protect switch; those switches form a set of resilient tabs thereby increasing the size of the connector. Therefore, the conventional connector with a relative large dimension is not adaptable for various digital or information appliances emphasizing light, thin, short and small types.

In viewing and in order to improve the abovementioned problems as well as to achieve the other effects and objectives, the inventor of the present invention researched and developed a common signal connector for a storage card.

### SUMMARY OF THE INVENTION

In order to meet the trend and need of having a light, thin, short and small portable device, as well as to make the connector capable of adapting various storage cards, the present invention provides a unitarily molded common signal connector with a lower cost to be conjoined with the connector thereof. One lateral side of the common connector is embedded with one or more than one row of contact terminals. There are three rows in the present invention. Merely, the design of having contact terminals in one or more than one row uses a single insert slot for storage cards, such as the Smart Media (SM) card, the Secure Digital (SD) Card, Multi Media Card (MMC) and Memory Stick (MS) Card of four different kinds of dimensions. Therefore, not only the volume and dimension of the connector is tremendously reduced, the strength thereof is relatively enhanced. In other words, inserting those storage cards will not change the external shape or increase the size of the connector of the present invention.

Another objective of the present invention is to make one end portion of the embedded contact terminals in row(s) protrude beyond the side where they are inserted to connect with a plurality of through holes disposed on a unitarily molded circuit board so as to tremendously simplify the manufacturing procedure and the mechanical structure thereof, reduce the cost and enhance the quality stability, eliminate the assembly of an upper and a lower base plates of a conventional connector as well as the necessary and complicate procedure of stretching contact terminals from the connector to connect with a circuit board.

The present invention utilizes the specialty of having relative close interval of the contact terminals of the SD, MMC or SM interfaces to merely adjust the horizontal and vertical positions of one row of the contact terminals of the SM card to simultaneously connect with the contact terminals of the SD or MMC interface. Therefore, it reduces the disposition of one set of the conventional contact terminals, eliminates the need to individually dispose the exclusive contact terminals for the interface contact feet of each of the storage card and reduces the error occurrence of inserting the cards to the wrong directions.

To enable a further understanding of the structural features and the effects of the present invention, the brief description of the drawings below is followed by the detailed description of the preferred embodiment.

### BRIEF DESCRIPTION OF THE DRAWINGS

FIG. 1 is an exploded drawing of a signal connector of a conventional storage card.

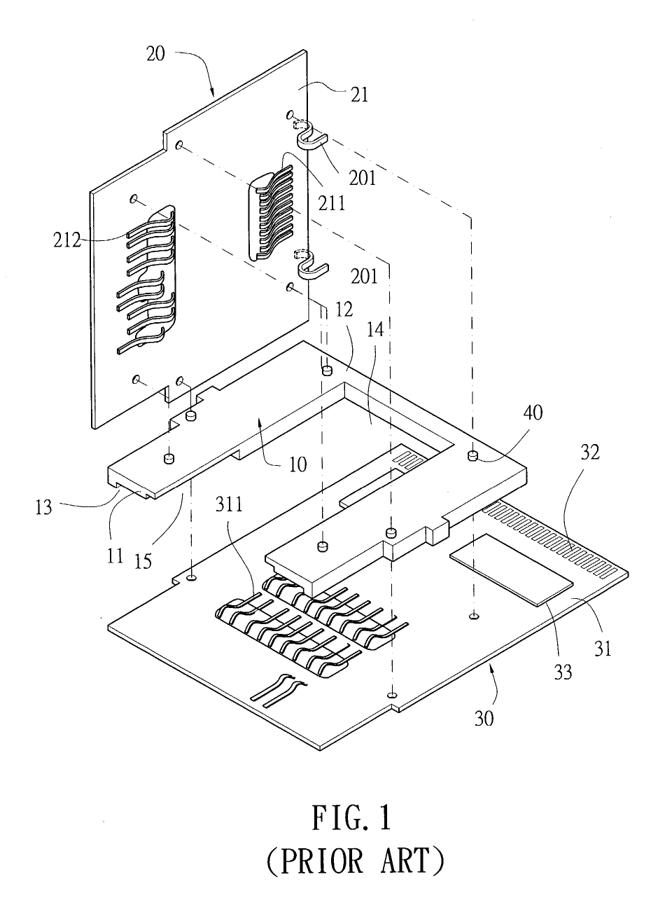

FIG. 2 is a pictorial drawing of the present invention of a common signal connector for a storage card.

FIG. 3 is an exploded drawing of the present invention of a common signal connector for a storage card.

FIG. 4 is a pictorial drawing of the present invention of a common signal connector connecting with a circuit board.

FIG. 5 is a bottom view and pictorial drawing of embedding the contacting terminal sets in FIG. 3 into the circuit board.

FIG. 6 is a lateral view and schematic drawing of FIGS. 3 and 4.

FIG. 7 is a pictorial and schematic drawing of connecting a frame according to FIG. 3.

FIG. 8 is a status drawing of inserting a Smart Media Card into the present invention.

FIG. 9 is a status drawing of inserting a Secure Digital/Multi Media Card into the present invention.

FIG. 10 is a status drawing of inserting a Memory Stick Card into the present invention.

### DETAILED DESCRIPTION OF THE PREFERRED EMBODIMENTS

The present invention utilizes the special fact that the interval of the contact terminals of a Secure Digital (SD)/Multi Media (MM) Card is relatively close to that of a Smart Media (SM) Card interface to merely adjust the horizontal and vertical positions of one row of the contact terminals of the SM card to simultaneously connect with the contact terminals of the SD/MM Card interface. In other words, the inventor makes nine contact terminals in one row (the first row in the present invention) of the two rows of twenty-two contact terminals of the SM Card share with the SD/MM Card thereby forming common contact terminals through adding proper electric control.

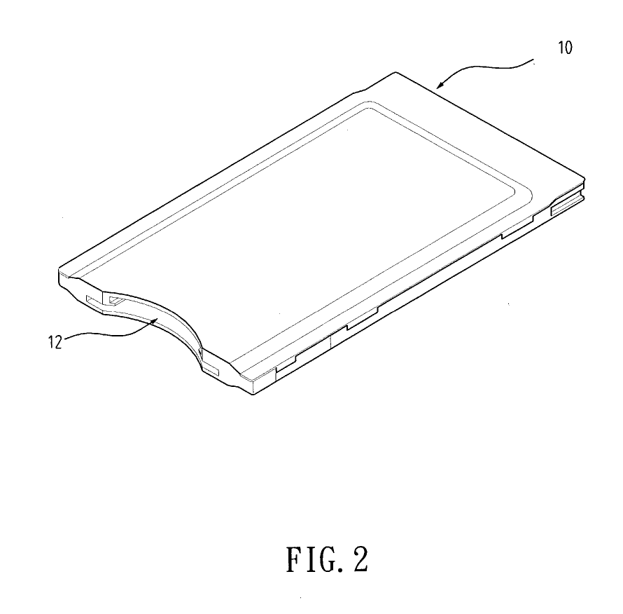

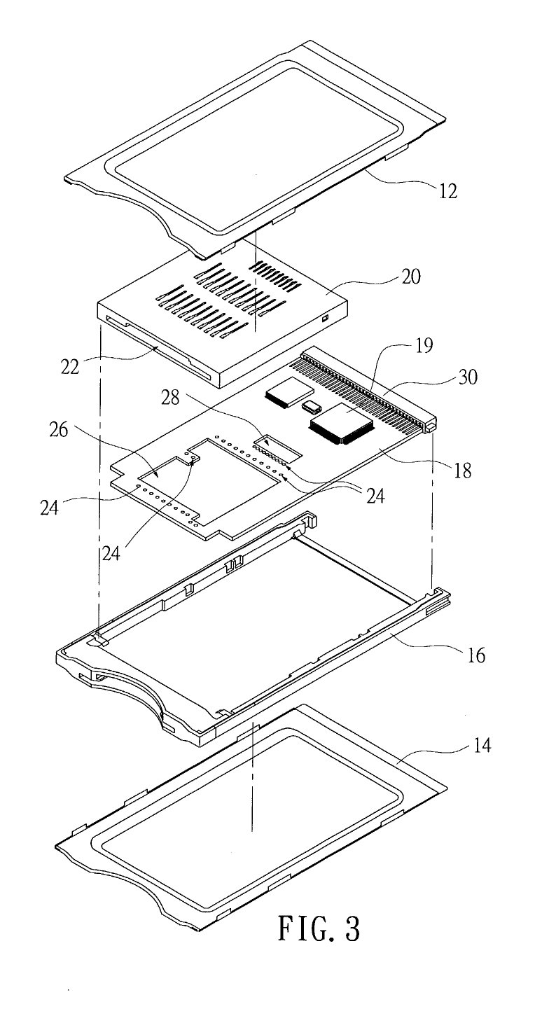

FIGS. 2 and 3 show the pictorial and exploded drawings of the present invention. The present invention of a common signal connector (10) for a storage card includes a circuit board (18) with a controller (19), a common connector (20) allowing the simultaneous insertion and positioning of storage cards of different dimensions, a frame (16), an upper and a lower metal plates (12, 14) fixed on the common connector (20).

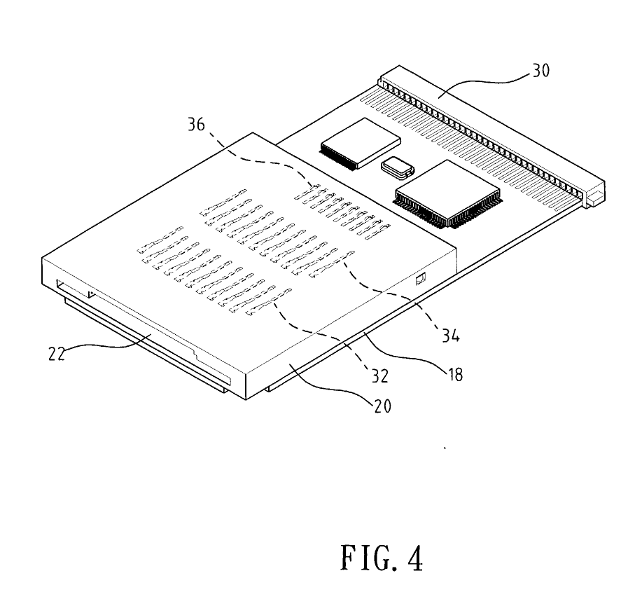

FIGS. 4, 5 and 6, show the pictorial, the bottom view, and the lateral view of the common connector connecting the circuit board. The common connector (20) is a unitarily molded insert slot (22) with a plurality of guide slots. The insert slot (22) of the guide slots and the card insertion position are respectively disposed with a fixed dull-preventing mechanism, a write-proof protect switch for and an insert detect switch for each card. These switches are of conventional structures and not be described here. More particularly, only one lateral side of the common connector (20) is disposed with contact terminals arranged in a plurality of rows (32, 34, 36) for respectively inserting and supporting four storage cards of different dimensions, such as the SD/MM, SM and MS Cards. What needs more emphasis is that one set of the three rows of contact terminals (32, 34, 36) can be shared by the contact terminals of more than two kinds of storage cards. That means it can be commonly used for SD/MM and SM cards.

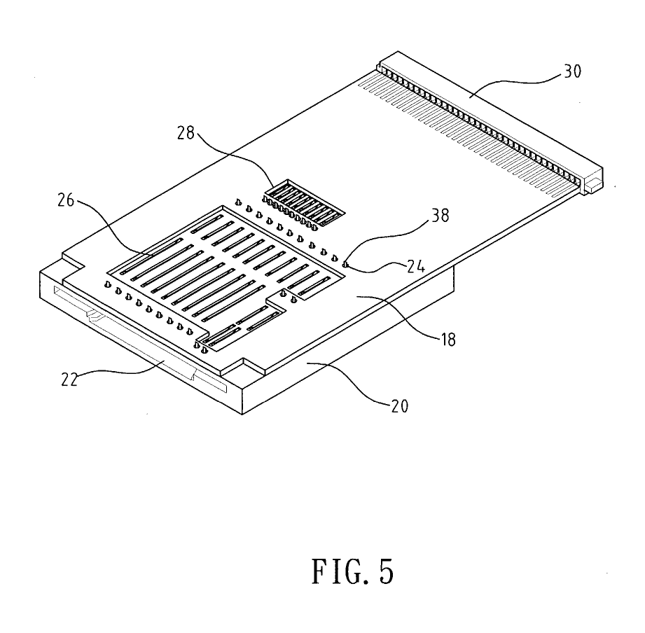

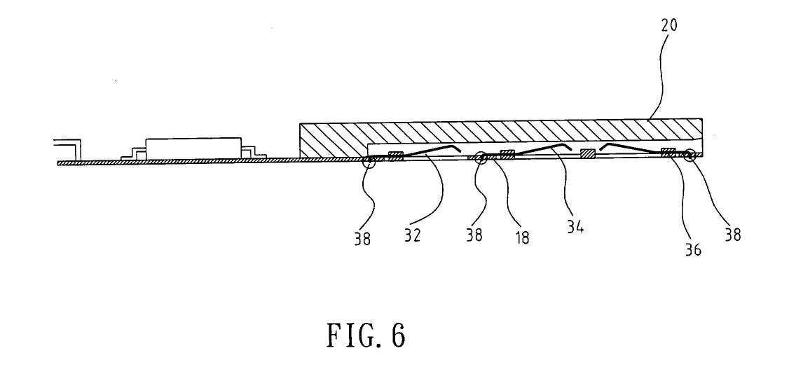

As indicated in FIGS. 5 and 6, one end portion of the rowed contact terminals (32, 34, 36) protrudes beyond the side. In other words, the protruding terminals (38) connect with a plurality of corresponding through holes (24) disposed on the circuit board (18) thereby directly controlling and converting the storage card signal into the connector interface signal for input and output through the circuit arrangement (not shown) on the circuit board (18). Wherein, two receptacle block holes (26, 28) are disposed on proper positions on the circuit board (18) to respectively keep away the embedding space of the rowed contact terminals (32, 34, 36).

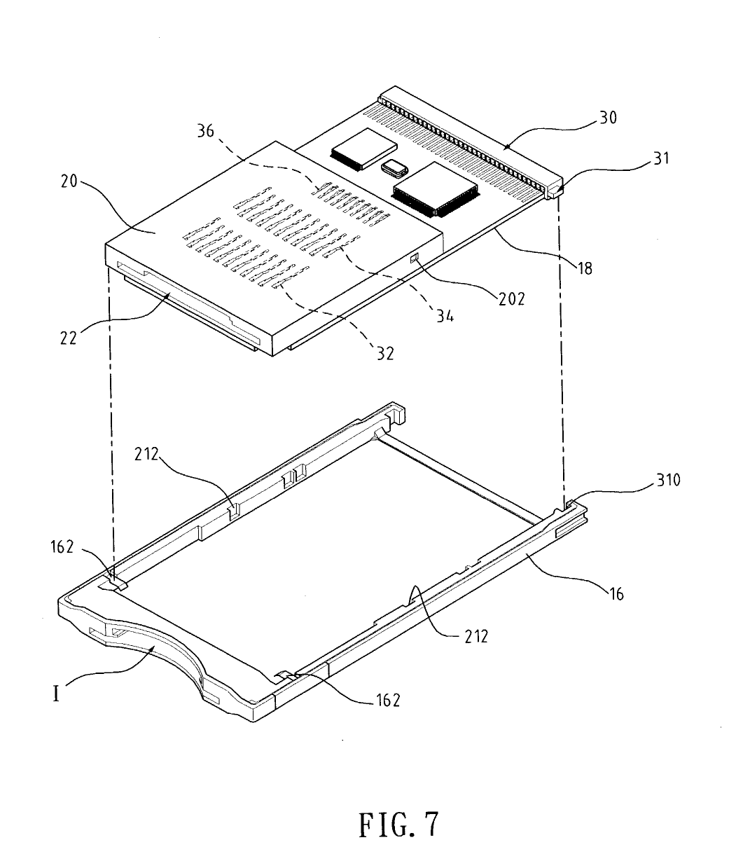

FIG. 7 shows a pictorial and schematic drawing to indicate that FIG. 3 connects with a frame. For further connecting the conjoined common connector (20) and the circuit board (18) with a frame (16), the proper positions on the periphery of the inner rim of the frame (16) are disposed with a plurality of clip slots (212) and position slots (310) for respectively positioning position points (202) on two sides of the common connector (20) and connection pieces (31) on two sides of a connector interface (30). Furthermore, a same receptacle (I) is disposed at the front end of the frame (16) opposite the common connector (20) for inserting the storage cards and line them flash with the receptacle (1).

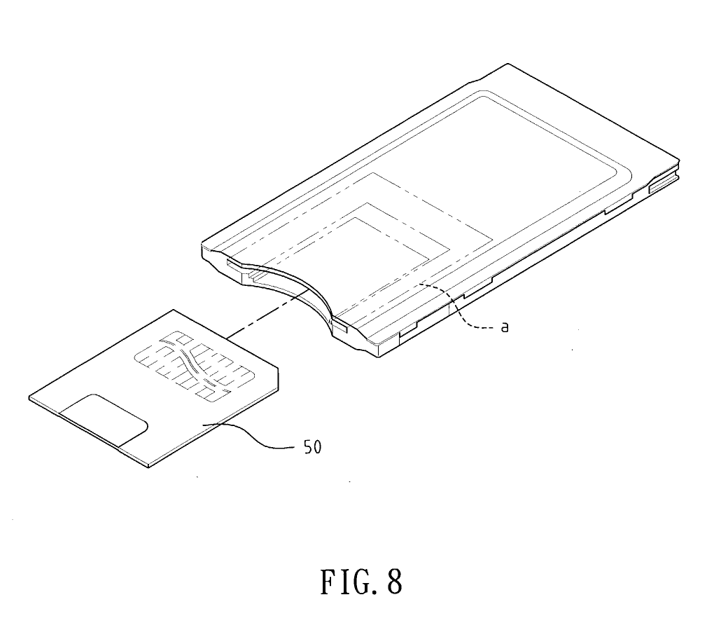

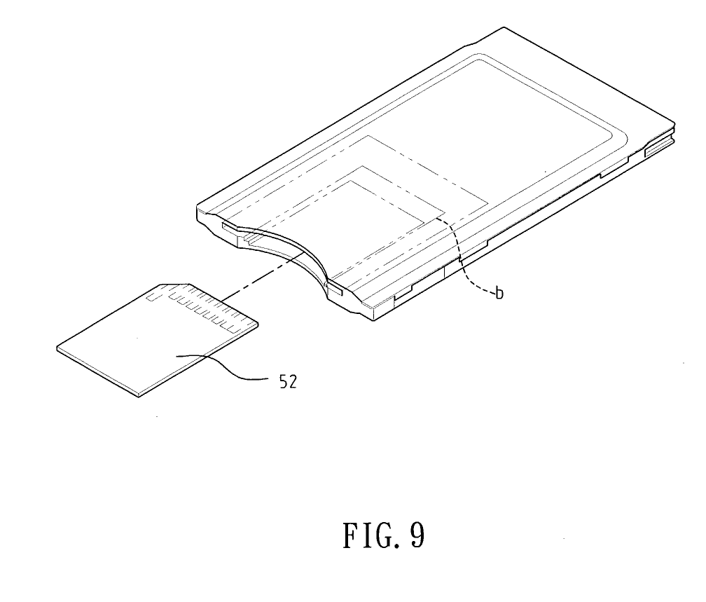

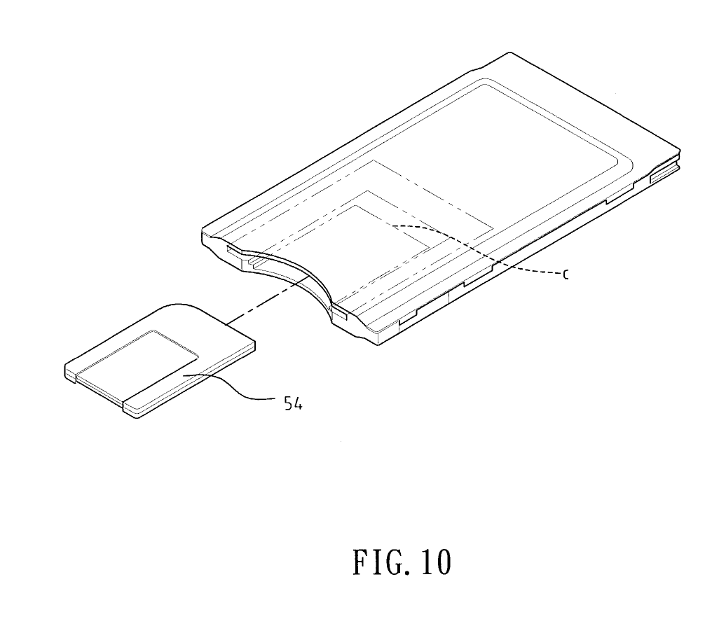

FIGS. 8, 9 and 10 show the status drawings of inserting the SM, SD/MM and MS Cards into the present invention. Wherein, the SM Card (50) is inserted in FIG. 8, the SD/MM Cards (52) in FIG. 9 and the MS Card (54) in FIG. 10. Those cards are respectively inserted into the slot positions (a, b, c) on the connector (10) of the present invention.

In summation of the abovementioned, the present invention of a common signal connector for a storage card has the following advantages:

1. The present invention provides a unitarily formed common connector at a lower cost to be conjoined with the connector of the present invention. One or more than one row of contact terminals are embedded into a single lateral side of the common connector; it allows these rowed contact terminals of the four storage cards, such as the SM, SD/MM and MS Cards of different dimensions to use the single insert slot.

2. The present invention makes one end portion of the contact terminals in rows protrude beyond the embedded side to conjoin with a plurality of corresponding through holes disposed on the unitarily molded circuit board thereby tremendously simplifying the manufacturing procedure and mechanical structure thereof, reducing the cost and enhancing the quality stability. Furthermore, it further eliminates the complicate manufacturing procedure of using the upper and the lower base plates to assemble the conventional connector; it requires no need of pulling extra terminals to connect the circuit board.

It is of course to be understood that the embodiment described herein is merely illustrative of the principles of the invention and that a wide variety of modifications thereto may be effected by persons skilled in the art without departing from the spirit and scope of the invention as set forth in the following claims.

1. A common signal connector for a storage card comprising a circuit board of a controller as well as a connector capable of inserting and positioning storage cards of various dimensions at different times is characterized that:
the connector is a unitarily molded insert slot with a plurality of guide slots; only one lateral side of the connector is disposed with one or more than one row of contact terminals; one end portion of the contact terminal protrudes beyond said lateral side to engage with a plurality of through holes of the corresponding circuit board thereby directly controlling and converting the storage card signal into the connector interface signal for input and output through the circuit arrangement on the circuit board.

2. The common signal connector for a storage card according to claim 1, wherein two receptacle block holes are disposed on the circuit board for respectively keeping away the embedding space of the rowed contact terminals.

3. The common signal connector for a storage card according to claim 1, wherein three rows of contact terminals support four storage cards—Secure Digital (SD) Card, Multi Media (MM) Card, Smart Media (SM) Card and Memory Stick (MS) Card of different dimensions; one contact terminal are capable of allowing the connection with contact terminals of two or more than two kinds of storage cards, such as SD/MM and SM Cards.

4. The common signal connector for a storage card according to claim 1, wherein the common connector is fixed by a frame and covered respectively by an upper and lower metal plates.

5. The common signal connector for a storage card according to claim 1, wherein a plurality of clip slots and position slots are disposed on the proper positions on the inner rim periphery of the frame to respectively fix with position points on two sides of the common connector and connection pieces disposed on two sides of the connector interface.
